(19) United States
(12) Patent Application Publication
(10) Pub. No.: US 2015/0126131 A1
(43) Pub. Date: May 7, 2015

(54) WIRELESS COMMUNICATION DEVICE AND MEASURING DEVICE THEREFOR

(71) Applicant: TAIYO YUDEN CO., LTD., Tokyo (JP)

(72) Inventor: Jin MIKATA, Tokyo (JP)

(73) Assignee: TAIYO YUDEN CO., LTD., Tokyo (JP)

(21) Appl. No.: 14/476,640

(22) Filed: Sep. 3, 2014

(30) Foreign Application Priority Data
Nov. 7, 2013 (JP) 2013-230893

(51) Int. Cl. H04B 17/00; H04B 1/44; H04M 1/24; G01R 21/00

(52) U.S. Cl. CPC H04B 17/0032; G01R 21/00; H04B 1/44; H04M 1/24
USPC 455/67.11; 455/83

(57) ABSTRACT

In a wireless communication device, a reactance element is connected in series between an input/output terminal of a wireless communication and an impedance-matching circuit. A measuring reactance element is provided in an external measuring device, and the types and circuit contacts of respective elements are chosen such that when the reactance element and the measuring reactance element are connected in parallel during power measurement, they together form a band-stop filter circuit that blocks signals of a prescribed frequency band outputted from the wireless communication circuit.

### BACKGROUND OF THE INVENTION

1. Technical Field

The present invention relates to a wireless communication device having an antenna connected to a wireless communication circuit mounted thereon and to a measuring device that measures output power of this wireless communication circuit. In particular, the present invention relates to a wireless device that can electrically isolate an antenna from a wireless communication circuit and then measure power, and also relates to this measuring device.

2. Description of Related Art

It is common for wireless communication devices used in mobile phones and the like to have an antenna built into the circuit substrate in order to achieve more compact sizes. It is necessary to evaluate the characteristics of such a wireless communication device after all the circuits have been mounted. The output power of the wireless communication circuit, in particular, must be measured when measuring output power, rather than measuring the radiation power emitted from the antenna.

If a configuration allowing for isolation of the antenna from the wireless communication circuit is not provided, then the antenna remains connected to the output end of the wireless communication circuit; thus, this configuration is susceptible to effects caused by variations in the antenna, impedance-matching circuit, or the examination environment such as differences in the structure of the examination jig. Therefore, the measurement values would be inaccurate, decrease yield, and necessarily lead to an increase in costs.

Due to this, it is vital to evaluate the characteristics of the wireless communication device after the antenna, impedance-matching circuit, and the like have been isolated.

A wireless communication device disclosed in Japanese Patent Application Laid-Open Publication No. 2002-353841 (Patent Document 1) having a switch that mechanically separates the wireless communication circuit from the antenna and impedance-matching circuit is proposed as a wireless communication device that can isolate the antenna and impedance matching-circuit. Providing the switch in this manner, however, is impossible these days when reductions in size are demanded at the millimeter level.

Furthermore, as described in Patent Document 1, using a connector to isolate the antenna in order to examine output power of the wireless communication circuit in the wireless communication device would lead to an increase in costs.

There is also a proposal for a pseudo-circuit to perform isolation at high frequencies without mechanically isolating the antenna and impedance-matching circuit from the wireless communication circuit. Japanese Patent No. 4239391 (Patent Document 2) discloses an example of such a wireless communication device. Patent Document 2 discloses an invention that achieves isolation of the antenna at high frequencies by a quarter wavelength transmission line having a prescribed characteristic impedance being provided between an input/output terminal and antenna of the wireless communication circuit. The antenna side of the transmission line that is at a 90° phase delay to the input/output terminal of the wireless communication circuit is connected to ground during characteristic evaluation.

This is problematic, however, due to the amount of space required to provide the quarter wavelength transmission line.

A method to solve this problem is proposed in Japanese Patent Application Laid-Open Publication No. 2013-131797 (Patent Document 3), which discloses a wireless communication device having a pi-type low-pass filter circuit that performs characteristic evaluation after isolation at high frequencies by a 90° phase delay at the connection point of this low-pass filter and the wireless communication circuit side.

### RELATED ART DOCUMENT

### Patent Document

Patent Document 1: Japanese Patent Application Laid-Open Publication No. 2002-353841

Patent Document 2: Japanese Patent No. 4239391

Patent Document 3: Japanese Patent Application Laid-Open Publication No. 2013-131797

### SUMMARY OF THE INVENTION

It is well known, however, that the wireless communication device disclosed in Patent Document 3 needs a separately provided pi-type low-pass filter and an impedance-matching circuit to match impedance between the antenna and the wireless communication circuit. This requires space to provide at least three reactance elements that form the isolating pi-type low-pass filter in addition to the normal circuit configuration, thereby greatly increasing the amount of space needed.

The present invention was made in view of the above problems and aims at providing a wireless communication device having a circuit that electrically isolates the impedance-matching circuit connected to the antenna from the wireless communication circuit while using as little area as possible, and a measuring device therefor.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present invention provides: a circuit substrate; an antenna disposed on the circuit substrate; a wireless communication circuit disposed on the circuit substrate so as to process signals sent and received through the antenna; an impedance-matching circuit that is disposed on the circuit substrate between the antenna and an input/output terminal of the wireless communication circuit; and a reactance element disposed on the circuit substrate and connected in series between the impedance-matching circuit and the input/output terminal of the wireless communication circuit, wherein two end terminals of the reactance element are accessible from an exterior so that the reactance element can be coupled in parallel to an externally provided measuring reactance element, and when so coupled, the reactance element and the measurement reactance element together constitute a band-stop filter that substantially blocks signals of a prescribed frequency band from the wireless communication circuit from reaching to the impedance-matching circuit.

According to such a wireless communication device, the impedance-matching circuit connected to the antenna can be electrically isolated from the wireless communication circuit by connecting a measuring reactance element in parallel to the reactance element through connection terminal electrodes forming a band-stop filter that blocks communication frequencies of the wireless communication circuit. In this state, power measurement of the input/output terminal of the wireless communication circuit is possible in the measuring terminal electrode.

Therefore, according to the wireless communication device of the present invention, only the reactance element is mounted, requiring very little area, and an increase in space can be reduced as compared to conventional configurations. This also makes it possible for high-precision output power measurement without being influenced by variation in antenna characteristics and the surrounding environment, which improves yield and lowers costs. Only a single reactance element needs to be provided, and thus, the increase in cost is small compared to the cost-reducing effect of the yield improving.

In another aspect, the present invention provides a measuring device for measuring output power at an input/output terminal of a wireless communication circuit provided in a wireless communication device, the wireless communication device including a reactance element, two end terminals of which are accessible from an exterior, one of the two end terminals being connected to the input/output terminal of the wireless communication circuit, the measuring device including: a measuring reactance element, two end terminals of which are configured to be connectable to the respective end terminals of the reactance element in the wireless communication device so that the measuring reactance element can be coupled in parallel to the reactance element, and when so coupled, the measuring reactance element and the reactance element in the wireless communication device together constitute a band-stop filter that substantially blocks signals of a prescribed frequency band from the wireless communication circuit in the wireless communication device from passing therethrough; and a power measuring circuit that is configured to measure power outputted at the input/output terminal of the wireless communication circuit in the wireless communication device while the band-stop filter is established.

According to such a measuring device, the measuring reactance element is connected in parallel to the reactance element of the wireless device in order to form a band-stop filter that blocks signals of a frequency outputted from the wireless communication circuit. This electrically isolates the impedance-matching circuit connected to the antenna from the wireless communication circuit in the wireless communication device, and power measurement of the input/output terminal of the wireless communication circuit is performed by the power measurement circuit thereafter. Accordingly, in the measuring device, only one measuring reactance element needs to be added, and thus, an increase in costs of the measuring device can be prevented.

In another aspect, the present invention provides a set of a wireless communication device and a measuring device designed therefor, the wireless communication devices including: a circuit substrate; an antenna disposed on the circuit substrate; a wireless communication circuit disposed on the circuit substrate so as to process signals sent and received through the antenna; an impedance-matching circuit that is disposed on the circuit substrate between the antenna and an input/output terminal of the wireless communication circuit; and a reactance element disposed on the circuit substrate and connected in series between the impedance-matching circuit and the input/output terminal of the wireless communication circuit, two end terminals of the reactance element being accessible by the measuring device, and wherein the measuring device comprises: a measuring reactance element, two end terminals of which are configured to be connectable to the respective end terminals of the reactance element in the wireless communication device so that the measuring reactance element can be coupled in parallel to the reactance element, and when so coupled, the measuring reactance element and the reactance element in the wireless communication device together constitute a band-stop filter that substantially blocks signals of a prescribed frequency band from the wireless communication circuit in the wireless communication device from reaching to the impedance-matching circuit in the wireless communication device; and a power measuring circuit that is configured to measure power outputted at the input/output terminal of the wireless communication circuit in the wireless communication device while the band-stop filter is established.

According to the wireless communication device of the present invention, the measuring reactance element is connected in parallel to the reactance element through connection terminal electrodes forming a band-stop filter, thereby electrically isolating the impedance-matching circuit connected to the antenna from the wireless communication circuit. In this state, power measurement of the input/output terminal of the wireless communication circuit is possible in the measuring terminal electrode.

Furthermore, according to the measuring device of the present invention, it is possible to perform power measurement of the input/output terminal of the wireless communication circuit with the power measuring circuit by forming a band-stop filter to electrically isolate the impedance-matching circuit connected to the antenna from the wireless communication circuit.

Accordingly, in the measuring device, only one measuring reactance element needs to be added, and thus, an increase in costs of the measuring device can be reduced.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is an external perspective view of a wireless communication device according to one embodiment of the present invention.

FIG. 2 is a cross-sectional view of main parts in FIG. 1 along the arrow A-A.

FIG. 3 is a circuit diagram of a wireless communication device according to the one embodiment of the present invention.

FIG. 4 is a circuit diagram of a measuring device according to the one embodiment of the present invention.

FIG. 5 is a cross-sectional view of the connective relationship between the wireless communication device and the measuring device during power measurement according to one embodiment of the present invention.

FIG. 6 is a circuit diagram of the connective relationship between the wireless communication device and the measuring device during power measurement according to one embodiment of the present invention.

FIG. 7 is a circuit diagram of a wireless communication device and a measuring device according to another embodiment of the present invention.

FIG. 8 is a view of passage loss characteristics when the number of measuring devices has been changed according to the other embodiment of the present invention.

FIG. 9 is a circuit diagram of power measurement being performed without measurement reactance elements being connected in the other embodiment of the present invention.

FIG. 10 is a view of passage loss characteristics when the number of measuring devices has been changed without the measurement reactance elements being connected in the other embodiment of the present invention.

### DETAILED DESCRIPTION OF EMBODIMENTS

Circuit substrates having a wireless communication circuit with a built-in antenna assumes the central role in mobile phones such as smartphones. For these devices, after manufacturing, it is necessary to isolate the impedance-matching circuit connected to the antenna from the wireless communication circuit in order to measure output power of the input/output terminal of the wireless communication circuit. At least some elements of the present invention make it possible to lower the cost of wireless communication devices and to assume a role in mass production.

Specifically, one aspect of the present invention is directed to a wireless communication device in which a single inductor device or capacitor is connected in series between the impedance-matching circuit and the wireless communication circuit, the impedance-matching circuit matching impedance between the antenna and wireless communication side. Another aspect of the present invention is directed to a measuring device for this wireless communication device. The normal impedance value of the input/output terminal of the wireless communication circuit is set at 50 ohms. In contrast, it is common to match the impedance of the antenna and the wireless communication circuit by using an impedance-matching circuit, due to the input impedance of the antenna not matching with 50 ohms because of variation in the antenna shape and dimensions or the installation environment. The inductor or capacitor provided between the impedance-matching circuit and the wireless communication circuit is configured to be connected in parallel with the measuring reactance element of the measuring device, or namely the capacitor or inductor, to form together a band-stop filter. With this configuration, the circuit contact of each circuit element is set so as to block signals of the frequency outputted from the wireless communication circuit. Due to this, the reactance element forming a portion of the band-stop filter need only be provided on the circuit substrate of the wireless communication device, and thus, the required circuit substrate can be made using a very small amount of area and a reduction in size and costs is possible.

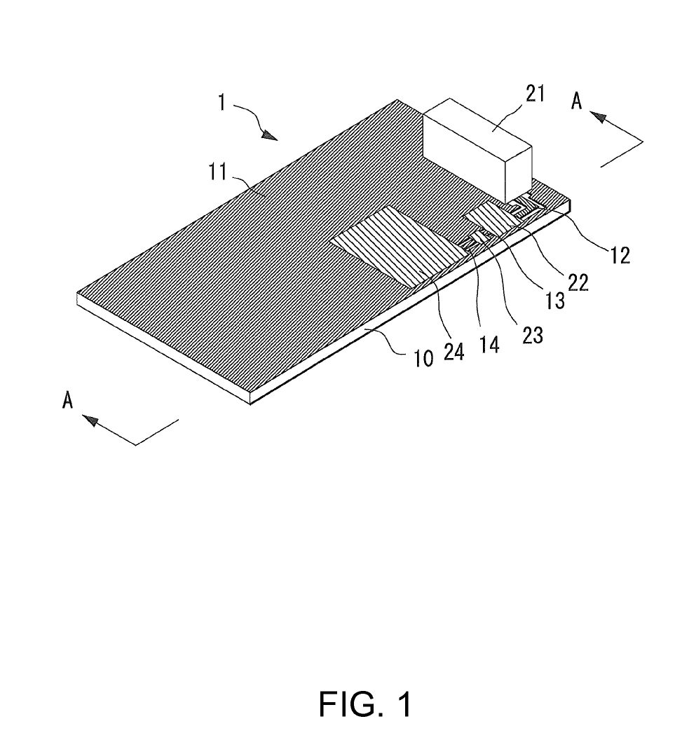

One embodiment of the present invention will be described below with reference to FIGS. 1 to 10.

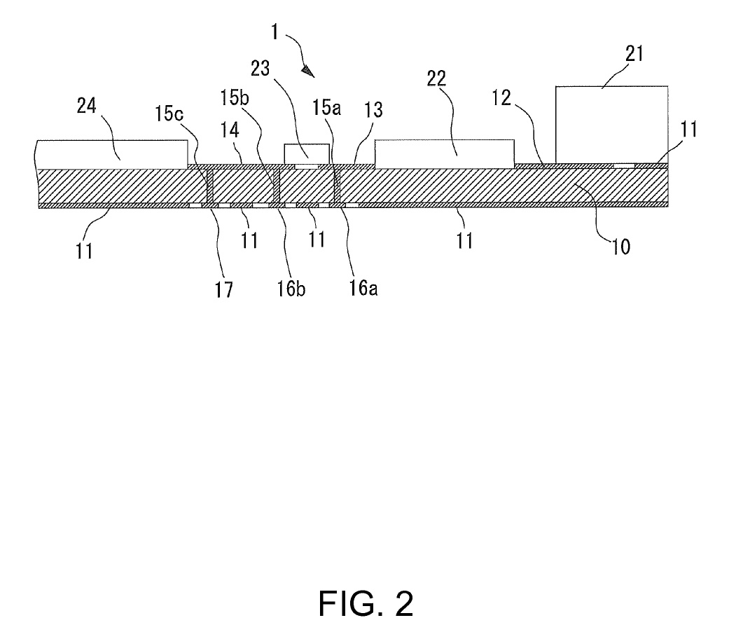

As shown in FIGS. 1 and 2, a wireless communication device 1 has a circuit substrate 10 and an antenna 21 mounted on one surface of the circuit substrate 10. An impedance-matching circuit 22, reactance element 23, and wireless communication circuit 24 are also provided on this one surface of the circuit substrate 10. A ground electrode 11 is provided on the areas of this surface of the circuit substrate 10 not used by the circuits and devices.

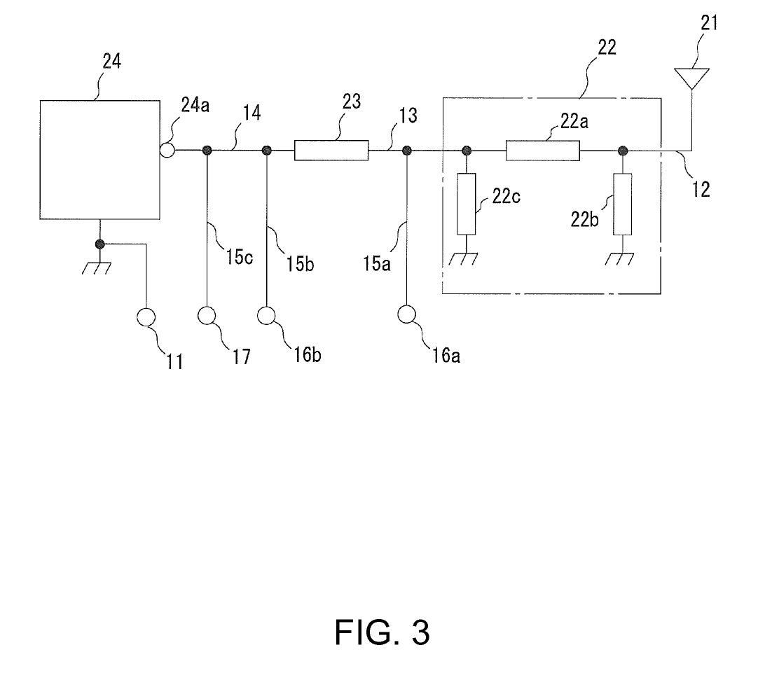

As shown in FIG. 3, the impedance-matching circuit 22 is formed by three reactance elements 22a to 22c being connected to a π-type. One end of the reactance element 22a is connected to a feeding point of the antenna 21 through a transmission line 12, and the other end of the reactance element 22a is connected to one end of the reactance element 23 through a transmission line 13. One end of the reactance element 22b is connected to one end of the reactance element 22a, and the other end of the reactance element 22b is connected to the ground electrode 11. One end of the reactance element 22c is connected to the other end of the reactance element 22a, and the other end of the reactance element 22c is connected to the ground electrode 11.

The other end of the reactance element 23 is connected to an input/output terminal 24a of the wireless communication circuit 24 through a transmission line 14.

One end of the reactance element 23 is connected to a connection terminal electrode 16a formed on the other surface of the circuit substrate 10 through a via conductor 15a, and the other end of the reactance element 23 is connected to a connection electrode 16b formed on the same other end of the circuit substrate 10 through a via conductor 15b. Furthermore, the input/output terminal 24a of the wireless communication device 24 is connected to a measuring terminal electrode 17 formed on the other surface of the circuit substrate 10 through a via electrode 15c. The ground electrode 11 is also formed on the edge face of the circuit substrate.

The impedance-matching circuit 22, the reactance element 23, and the wireless communication circuit 24 may be respectively formed by ICs or chip components mounted on the surface of the circuit substrate 10, or may be formed by conductors or chip components and the like disposed inside the circuit substrate 10.

Although not shown in FIGS. 1 and 2, it is common for an insulating film to be formed on the ground electrode 11 and the transmission lines 12, 13, and 14 through insulation coating or the like in order to protect these.

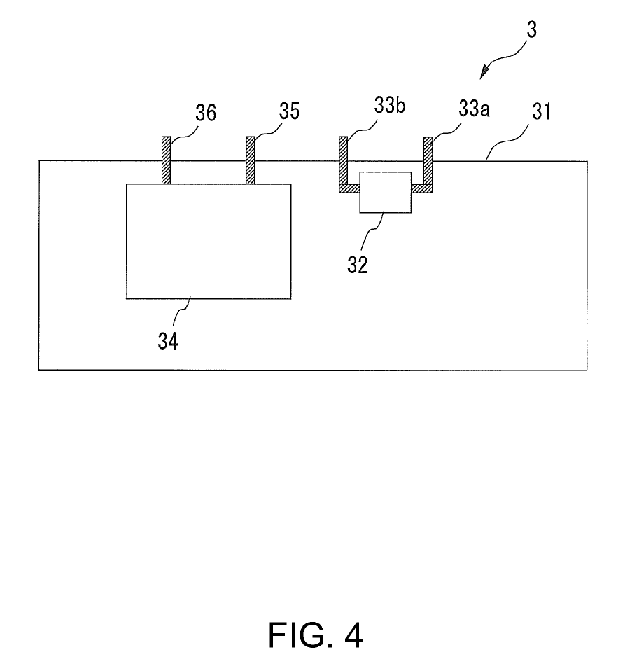

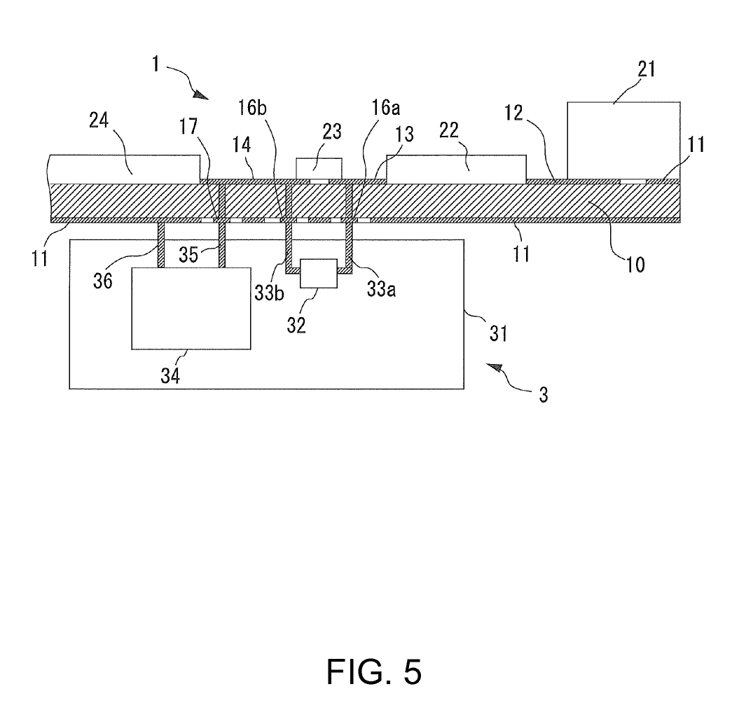

As shown in FIGS. 4 and 5, a measuring device 3 is formed by a measuring reactance element 32 and a power measuring circuit 34 disposed in a case 31. One end of the measuring reactance element 32 is connected to a connection terminal 33a that has an open end protruding above the case 31, and the other end of the measuring reactance element 32 is connected to a connection terminal 33b that has an open end protruding above the case 31.

One measuring end of the power measuring circuit 34 is connected to a measuring terminal 35 that has an open end protruding above the case 31, and the other measuring end (ground) of the power measuring circuit 34 is connected to a connection terminal 36 that has an open end protruding above the case 31.

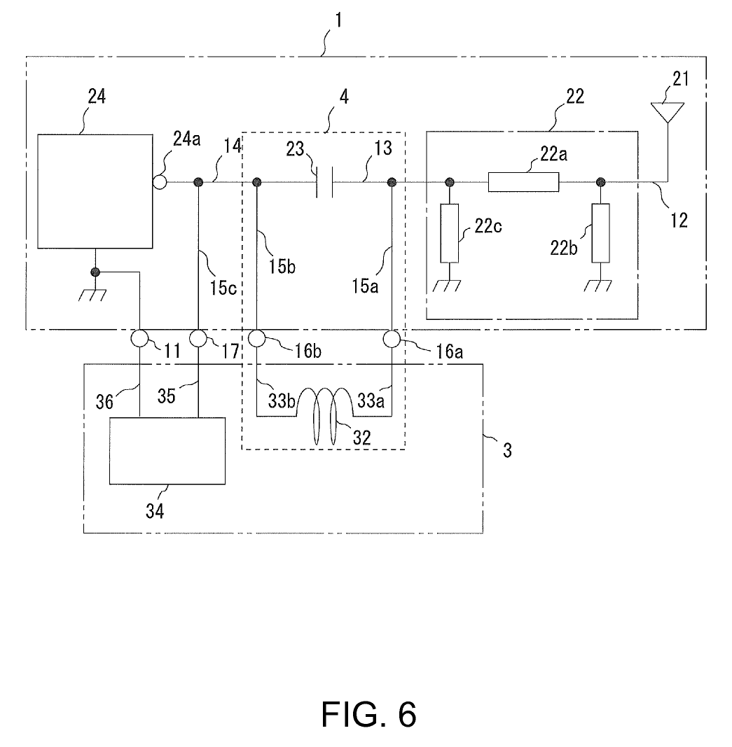

As shown in FIG. 5, the top of the measuring device 3 and the bottom surface of the circuit substrate 10 of the wireless communication device 1 face each other during power measurement of the wireless communication circuit 24. The connection terminal 33a abuts the connection terminal electrode 16a, the connection terminal 33b abuts the connection terminal electrode 16b, the measuring terminal 35 abuts the measuring terminal electrode 17, and the connection terminal 36 abuts the ground electrode 11. As shown in FIG. 6, this electrically connects the wireless communication device 1 to the measuring device 3.

As shown in FIG. 6, in the above-mentioned configuration, the reactance element 23 of the wireless communication device 1 and the measuring reactance element 32 of the measuring device 3 are connected in parallel to form a band-stop filter circuit 4 that blocks signals of the frequencies outputted by the wireless communication circuit 24. The circuit elements are chosen such that if one of the reactance element 23 and the measuring reactance element 32 is an inductor, the other device is a capacitor, for example. If the output frequency of the wireless communication circuit 24 is f, then in order for the resonance frequency of the band-stop filter circuit 4 formed by the reactance element 23 and the measuring reactance element 32 to become f, an inductance L and a capacitance C are configured so as to effectively satisfy formula (1) below when the inductance is L (H) and the capacitance is C (F) in the band-stop filter circuit 4.

f=1/{2π(LC)^{1/2}} (1)

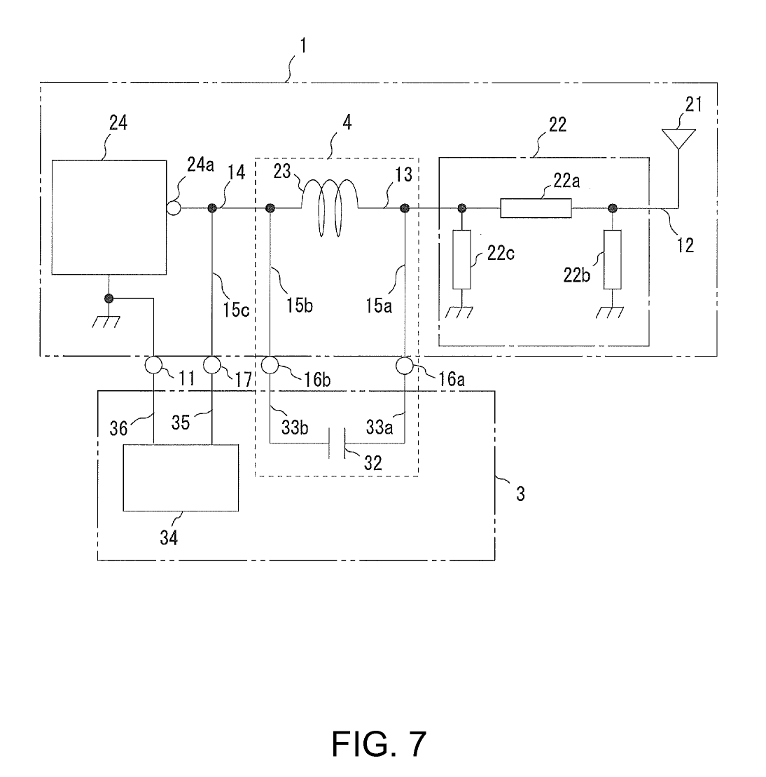

The circuit configuration in FIG. 6 shows the reactance element 23 as the capacitor and the measuring reactance element 32 as the inductor. In contrast, the circuit configuration in FIG. 7 shows the reactance element 23 as the inductor and the measuring reactance element 32 as the capacitor. In both cases, the band-stop filter circuit 4 that blocks signals of the frequency outputted by the wireless communication circuit 24 is formed by the reactance element 23 and the measuring reactance element 32 being connected in parallel. Due to this, the input/output terminal 24a of the wireless communication circuit 24 can be electrically isolated from the impedance-matching circuit 22 by the band-stop filter circuit 4 during power measurement. Accordingly, power measurement can be performed without being influenced by the antenna 21, impedance-matching circuit 22 or the like and the surrounding environment thereof.

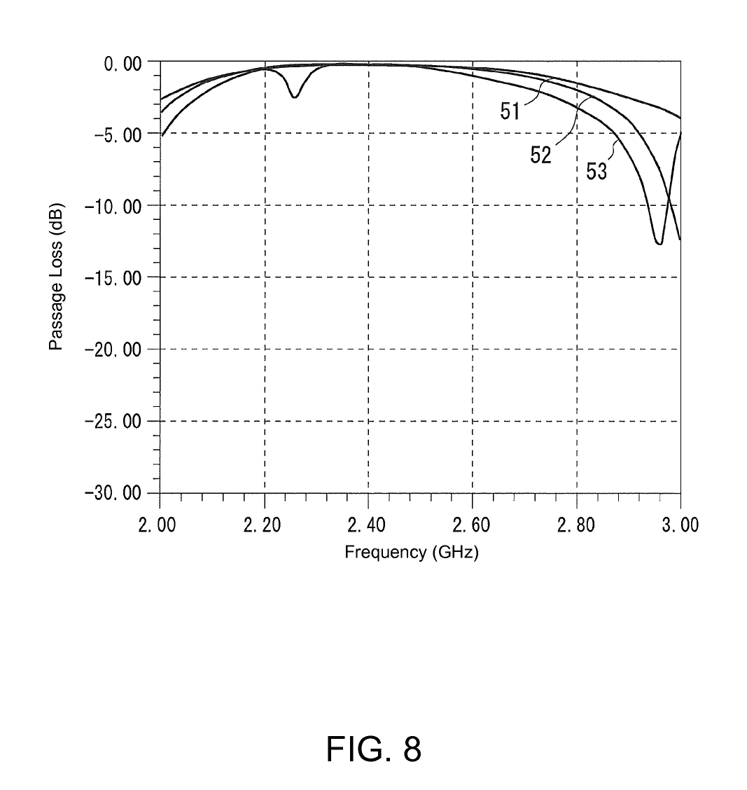

The operations of the wireless communication circuit 24 and the power measuring circuit 34 are explained in more detail in the case of using a 2.4 to 2.5 GHz band as an example. FIG. 8 is a graph showing passage loss characteristics between the input/output terminal 24a of the wireless communication circuit 24 and one measuring end of the power measuring circuit 34 during power measurement in the circuit configuration in FIG. 7. In FIG. 8, a characteristic curve 51 shows the reactance element 22a of the impedance-matching circuit 22 having a capacitance of 1.2 pF and the reactance element 22c having an inductance of 3.0 nH. A characteristic curve 52 shows the reactance element 22a of the impedance-matching circuit 22 having a capacitance of 1.2 pF and the reactance element 22c having an inductance of 4.0 nH. A characteristic curve 53 shows the reactance element 22a of the impedance-matching circuit 22 having a capacitance of 3.0 pF and the reactance element 22c having an inductance of 4.0 nH. As shown in FIG. 8, there is almost no influence from the impedance-matching circuit 22 during power measurement.

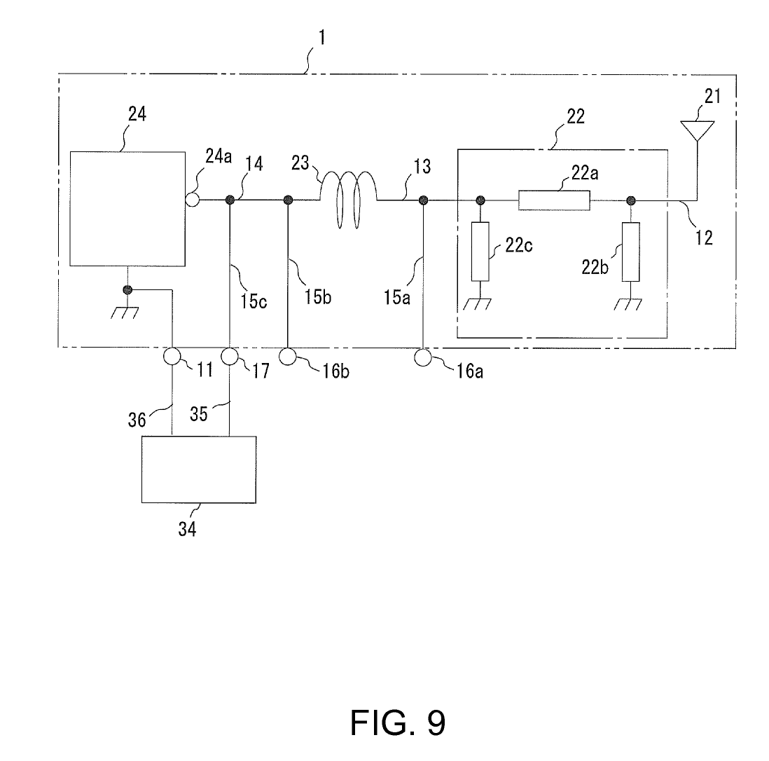

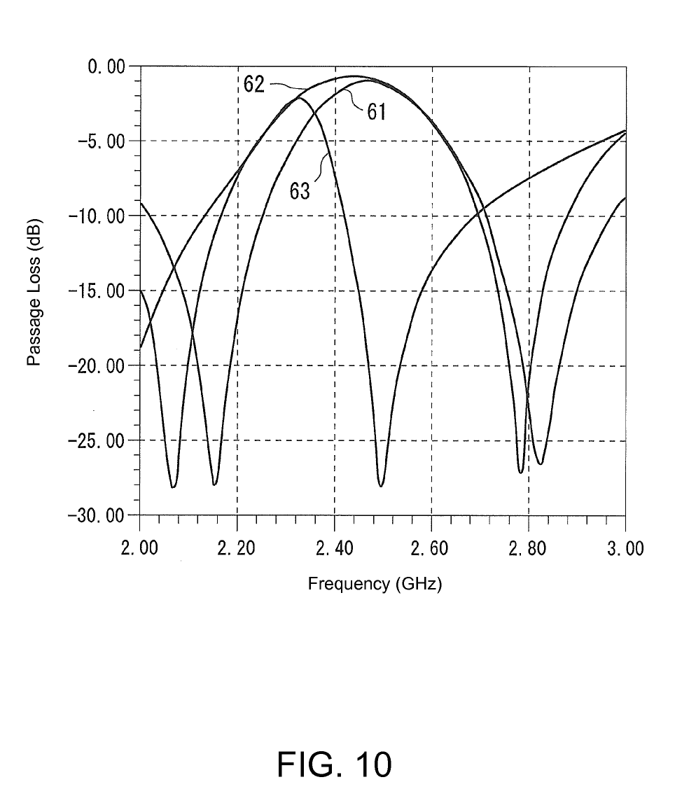

For comparison, FIG. 10 shows passage loss characteristics between the input/output terminal 24a of the wireless communication circuit 24 and one measuring end of the power measuring circuit 34 when only the power measuring circuit 34 is used without connecting the measuring reactance elements 32, as shown in FIG. 9. In FIG. 10, a characteristic curve 61 shows the reactance element 22a of the impedance-matching circuit 22 having a capacitance of 1.2 pF and the reactance element 22c having an inductance of 3.0 nH. A characteristic curve 62 shows the reactance element 22a of the impedance-matching circuit 22 having a capacitance of 1.2 pF and the reactance element 22c having an inductance of 4.0 nH. A characteristic curve 63 shows the reactance element 22a of the impedance-matching circuit 22 having a capacitance of 3.0 pF and the reactance element 22c having an inductance of 4.0 nH. As shown in the figure, there is a large amount of influence from the impedance-matching circuit 22 during power measurement.

As described above, connecting the reactance element 23 of the wireless communication device 1 and the measuring reactance element 32 of the measuring device 3 in parallel during power measurement forms the band-stop filter circuit 4, which raises the impedance value of the antenna as seen from the wireless communication circuit 24 and blocks signals of frequencies subject to examination. After power measurement has ended, the measuring reactance element 32 is removed, and the reactance element 23 and the impedance-matching circuit 22 are combined to match the impedance of the antenna 21 to the input/output terminal impedance of the wireless communication circuit 24.

Therefore, according to the wireless communication device 1 in the present embodiment, by merely providing the reactance element 23 on the circuit substrate 10 in a manner accessible by the measurement device, the reactance element 23 of the wireless communication device 1 and the measuring reactance element 32 of the measuring device 3 can be connected in parallel to form the band-stop filter circuit 4 during measurement. With this configuration, it is possible to electrically isolate the impedance-matching circuit 22 from the wireless communication circuit 24 during the measurement. Furthermore, in the wireless communication device 1, only one reactance element 23 needs to be added and the area required for this is very small. This makes it possible to prevent a large increase in space that would be required in conventional configurations, and a large increase in costs will not be incurred. In the measuring device 3, only one measuring reactance element 32 needs to be added, and thus, there is no significant increase in costs of the measuring device 3.

The use of a chip antenna in the embodiment above is described as an example, but other antenna such as a pattern antenna may be used, and differences in the shape of the antenna will not affect the present invention.

The reactance element 23 and the reactance element 32 are not limited to chip components, and may be other circuit elements or the like, such as elements formed by copper foil patterns on the substrate, as long as they have prescribed reactances, without regard to the type thereof.

In the embodiment described above, the frequencies of the wireless communication circuit were explained as being 2.4 to 2.5 GHz. However, the present invention is not limited to this. The present invention can be used with any frequency band.

In FIGS. 4 to 7, the measuring device 3 was described as being placed on the bottom of the circuit substrate 10 in performing power measurement, but other measuring devices and methods may also be used. Referring to FIG. 5, measurement is possible even if the measuring device 3 is disposed in a location corresponding to the top of the circuit substrate 10, for example. In other words, the top of the circuit substrate 10 may face the measuring device 3, and the connection terminals 33a and 33b may be connected to the respective ends of the reactance element 23. In a similar manner, the measuring terminal 35 and the connection terminal 36 of the power measuring circuit 34 may be configured so as to be respectively connected to the transmission line 14 and the ground electrode 11 at positions corresponding to the top of the circuit substrate 100. Accordingly, the connection terminal electrodes 16a and 16b or the measuring terminal electrode 17 and the like may be preferably provided, but do not necessarily have to be provided. When an insulating layer is disposed on the connection areas described above, by providing contact holes in the respective areas, power measurements are still possible.

In FIG. 6, the impedance-matching circuit 22 was described as a pi-type impedance-matching circuit, but it is possible to use other types of circuits such as an L-type or T-type, as long as the circuit can match the input impedance of the antenna 21 to the impedance (normally 50 ohms) of the input/output terminal of the wireless communication circuit 24 together with the reactance element 23.

### INDUSTRIAL APPLICABILITY

It will be apparent to those skilled in the art that various modification and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A wireless communication device, comprising:
a circuit substrate;
an antenna disposed on the circuit substrate;
a wireless communication circuit disposed on the circuit substrate so as to process signals sent and received through the antenna;
an impedance-matching circuit that is disposed on the circuit substrate between the antenna and an input/output terminal of the wireless communication circuit; and
a reactance element disposed on the circuit substrate and connected in series between the impedance-matching circuit and the input/output terminal of the wireless communication circuit,
wherein two end terminals of the reactance element are accessible from an exterior so that the reactance element can be coupled in parallel to an externally provided measuring reactance element, and when so coupled, the reactance element and the measurement reactance element together constitute a band-stop filter that substantially blocks signals of a prescribed frequency band from the wireless communication circuit from reaching to the impedance-matching circuit.

2. The wireless communication device according to claim 1, wherein the reactance element is an inductor.

3. The wireless communication device according to claim 1, wherein the reactance element is a capacitor.

4. A measuring device for measuring output power at an input/output terminal of a wireless communication circuit provided in a wireless communication device, said wireless communication device including a reactance element, two end terminals of which are accessible from an exterior, one of said two end terminals being connected to the input/output terminal of the wireless communication circuit, the measuring device comprising:
a measuring reactance element, two end terminals of which are configured to be connectable to the respective end terminals of the reactance element in the wireless communication device so that the measuring reactance element can be coupled in parallel to the reactance element, and when so coupled, the measuring reactance element and the reactance element in the wireless communication device together constitute a band-stop filter that substantially blocks signals of a prescribed frequency band from the wireless communication circuit in the wireless communication device from passing therethrough; and
a power measuring circuit that is configured to measure power outputted at the input/output terminal of the wireless communication circuit in the wireless communication device while the band-stop filter is established.

5. The measuring device according to claim 4,
wherein the reactance element of the wireless communication device is an inductor, and
wherein the measuring reactance element is a capacitor.

6. The measuring device according to claim 4,
wherein the reactance element of the wireless communication device is a capacitor, and
wherein the measuring reactance element is an inductor.

7. A set of a wireless communication device and a measuring device designed therefor, the wireless communication devices comprising:
a circuit substrate;
an antenna disposed on the circuit substrate;
a wireless communication circuit disposed on the circuit substrate so as to process signals sent and received through the antenna;
an impedance-matching circuit that is disposed on the circuit substrate between the antenna and an input/output terminal of the wireless communication circuit; and
a reactance element disposed on the circuit substrate and connected in series between the impedance-matching circuit and the input/output terminal of the wireless communication circuit, two end terminals of the reactance element being accessible by the measuring device, and
wherein the measuring device comprises:
a measuring reactance element, two end terminals of which are configured to be connectable to the respective end terminals of the reactance element in the wireless communication device so that the measuring reactance element can be coupled in parallel to the reactance element, and when so coupled, the measuring reactance element and the reactance element in the wireless communication device together constitute a band-stop filter that substantially blocks signals of a prescribed frequency band from the wireless communication circuit in the wireless communication device from reaching to the impedance-matching circuit in the wireless communication device; and
a power measuring circuit that is configured to measure power outputted at the input/output terminal of the wireless communication circuit in the wireless communication device while the band-stop filter is established.
